(19) United States
(12) Patent Application Publication
(10) Pub. No.: US 2012/0214319 A1
(43) Pub. Date: Aug. 23, 2012

(54) METHOD OF IMPROVING THE PASSIVATION EFFECT OF FILMS ON A SUBSTRATE

(75) Inventor: Yuanchang Zhang, Columbus, OH (US)

(73) Assignee: Natcore Technology, Inc., Red Bank, NJ (US)

(21) Appl. No.: 13/396,286

(22) Filed: Feb. 14, 2012

Related U.S. Application Data
(60) Provisional application No. 61/442,461, filed on Feb. 14, 2011.

(51) Int. Cl. H01L 21/263

(52) U.S. Cl. 438/799; 257/E21.333

(57) ABSTRACT

A film deposited on substrate may originally has a high surface recombination velocity (SRV). In order to suppress the SRV and increase the minority carrier lifetime, the substrate may be treated annealing at a high temperature in gas ambient containing O₂ or O²⁻. The substrate may also be treated annealing at a low or mild temperature in gas ambient containing H₂ or H⁺. The process has been found to improve the passivation effect of silicon oxide thin films on a silicon substrate. Further, the process can be achieved using the same production steps normally applied to the solar cell to create its top and bottom metal contacts without additional heating cycles are required.

### RELATED APPLICATIONS

This application claims the benefit of U.S. Provisional Patent Application No. 61/442,461 to Yuanchang Zhang, filed on Feb. 14, 2011, which is incorporated herein by reference.

### FIELD OF THE INVENTION

This invention relates to improving the passivation effect of a substrate with a film, and more particularly to silicon oxide thin films on a silicon substrate.

### BACKGROUND OF INVENTION

Crystalline silicon solar cell remains the most popular product in the photovoltaic industry in spite of the challenge from other low cost but low efficiency product such as thin film solar cell. The trend to go for thinner wafer calls for the application of advanced solar cell design. PERC (Passivated Emitter and Rear Cell) structure developed in 1980's are one of the most popular approaches for low cost high efficiency solar cell production, which has been scaled up by Suntech as the Pluto solar cell.

Surface passivation is a vitally important issue for PERC design. Surface passivation may be described as a process which reduces the density of available electronic states present at the surface of a semiconductor, thereby limiting hole and electron recombination possibilities. A high surface recombination velocity of electron and hole reduces the light generated current extracted by the solar cell therefore lower the cell efficiency. The so called “dangling bonds” in an incomplete surface usually act as the recombination centers for the hole and electron generated at the surface or approaching to the surface from inside. Surface passivation attempts to erase or disable these recombination centers. There are a few ways to accomplish surface passivation, including dielectric film coating on the surface to satisfy the dangling bonds, using an electric field to repel the minority carriers from the surface, or a combination thereof.

Another method for the passivation of silicon (Si) surfaces is the thermal oxidation at high temperature (˜1000° C.). Thermal oxide is perfect for the rear surface passivation with an “alneal” process (an annealing process for thermal oxide coated by Aluminum film). However, the high temperature as well as long time process during the thermal oxide growth can severely degrade the bulk carrier lifetime and are undesirable from production cost and throughput considerations. Hence, significant effort has been devoted in recent years to the development of low temperature (<500° C.) surface passivation schemes as an alternative to the high temperature oxidation of silicon. One successful approach is plasma enhanced chemical vapor deposition (PECVD) of silicon nitride (SiNₓ). PECVD grown SiNₓ is currently popular in the Si solar cell manufacturing process due to the ability to provide both anti-reflectance and surface passivation of the cell. Other alternatives of dielectric material include Al₂O₃ grown by atomic layer deposition (ALD), amorphous Si, and the like.

Liquid phase deposition (LPD) silicon oxide represents a low cost process to deposit silicon oxide on silicon at nearly room temperature, by preventing using high temperature furnace or large vacuum deposition chamber. However, the as-deposited silicon samples usually show poor surface passivation effect, for example, low minority carrier lifetime. The following description describes a process that enhances the surface passivation of substrates with poor surface passivation.

### SUMMARY OF THE INVENTION

In an illustrative implementation, a film deposited on substrate may originally have a high surface recombination velocity (SRV). By annealing in a gas ambient containing O₂ or O²⁻ at high temperature annealing and/or annealing in a Forming Gas (FG) at mild temperature, the SRV is extremely suppressed and the minority carrier lifetime shows orderly increased. Additionally, the passivation may be achieved using the same production steps normally applied to the solar cell to create its top and bottom metal contacts, and no additional heating cycles are required. The synergistic nature of this technology with existing cell fabrication steps will greatly simplify the standard silicon solar cell manufacturing process.

The foregoing has outlined rather broadly various features of the present disclosure in order that the detailed description that follows may be better understood. Additional features and advantages of the disclosure will be described hereinafter.

### BRIEF DESCRIPTION OF THE DRAWINGS

For a more complete understanding of the present disclosure, and the advantages thereof, reference is now made to the following descriptions to be taken in conjunction with the accompanying drawings describing specific embodiments of the disclosure, wherein:

FIGS. 1a and 1b show effective minority carrier lifetime comparison between the as-deposited sample, after O₂ annealing, and after O₂+FG annealing for p-type wafers and n-type wafers;

FIGS. 2a and 2b show measured effective lifetime of samples after six weeks of storage in an ambient cleanroom for p-type wafers and n-type wafers;

FIG. 3 shows the effective lifetime of post-annealed samples; and

FIG. 4 shows secondary ion mass spectrometry (SIMS) measurements of LPD SiOₓ film on Si substrate before, after annealing in O₂, and after annealing in O₂+FG.

### DETAILED DESCRIPTION

Refer now to the drawings wherein depicted elements are not necessarily shown to scale and wherein like or similar elements are designated by the same reference numeral through the several views.

Referring to the drawings in general, it will be understood that the illustrations are for the purpose of describing particular embodiments of the disclosure and are not intended to be limiting thereto. While most of the terms used herein will be recognizable to those of ordinary skill in the art, it should be understood that when not explicitly defined, terms should be interpreted as adopting a meaning presently accepted by those of ordinary skill in the art.

A thin film deposited on substrate, such as by a LPD method at near room temperature, may have a high surface recombination velocity (SRV). Nonlimiting examples of a thin film may include metal oxides with a formulation as MₓO_{y} or LₓM_{y}O_{z} (where L and M are metal elements, O is oxygen element); metal sulfides with a formulation as MₓS_{y} (M is metal elements, S is sulfur element); and metal selenides with a formulation MₓSe_{y} (M is metal elements, Se is selenium element). For example, thin films, such as silicon oxide (SiOₓ), SiO₂, TiO₂, ZrO₂, In₂O₃, SnO₂, BaTiO₃, ZnS, Bi₂Se₃, and/or the like, may be placed on a silicon substrate in solar cells. By treatment of O₂ high temperature annealing and/or mild temperature Forming Gas (FG) annealing, the SRV is extremely suppressed and the minority carrier lifetime shows orderly increased. In other implementations, O₂ may be substituted with any gas ambient that contains O₂ or O²⁻, such as, but not limited to, purified air, purified oxygen, N₂ and O₂ mixture, purified DI water steam, or the like. In other implementations, the FG may be substituted with any gas ambient that contains H₂ or H⁺, such as, but not limited to, purified H₂, purified DI water steam, or the like. The first annealing step in O₂ ambient at 700-1050° C. may be for a duration of 30-120 seconds. The second annealing step in a Forming Gas at 500° C. may be for a duration of 300 seconds or greater. It will be recognized that annealing duration is highly dependent on temperature. In some implementations, annealing duration for the second annealing steps may be 60 seconds or greater. In some implementations, the annealing temperature may be in the range of approximately 200-600° C. This passivation is achieved using the same production steps normally applied to the solar cell to create its top and bottom metal contacts, and no additional heating cycles are required. The synergistic nature of this technology with existing cell fabrication steps will greatly simplify the standard silicon solar cell manufacturing process.

The O₂ annealing process may preferably performed in a fast firing furnace in a Si solar cell product line designed for the metal contact so that no additional heat cycles are needed. Considering that the optimal temperature/dwelling time might be harsh for currently widely used screen printed metal pastes that work with SiNₓ, alternative electrode materials may be desired, such a metal paste material, suitable deposited metal film, or the like that works reasonably during the O₂ annealing process.

Possible variations may include, but are not limited to:
O₂ ambient in the first annealing step might be substituted by any gas ambient that contain O₂ or O²⁻, such as purified air, purified oxygen, N₂ and O₂ mixture, purified DI water steam, or the like.
Forming Gas ambient in second annealing step might be substituted by any gas ambient that contain H₂ or H⁺, such as purified H₂, purified DI water steam, or the like.

The following experimental examples are provided for illustrative purposes only. The various aspects described in the examples merely represent exemplary implementations. It will be recognized by one of ordinary skill in the art that various changes can be made in the implementations described without departing from the spirit and scope of the present disclosure.

Sample Preparation:

The reagent solution for the LPD growth of silica was prepared by saturating a ratio of 1 liter of 3 M hexafluorosilicic acid (H₂SiF₆) with 60 g 0.007 μm fumed silica powder at room temperature. After overnight saturation, the solution was filtered, first with a course VWR Grade 315 fluted filter for 25 μm particle retention, then with the Millipore Stericap system using 0.22 μm filters. The solution was then diluted to 1 M by adding 18 MOhm DI water.

The addition of water initiated the reaction and precipitated the silica according to

H₂SiF₆+2H₂O→SiO₂↓+6HF

Both N-type doped and P-type doped silicon wafers with a resistivity of about 3 Ohm-cm and a thickness of about 525 μm were used. The silicon wafers cleaned by standard procedures were immersed in the solution at a temperature of 30° C. The silicon dioxide film was deposited on the wafers with a growth rate about 40 nm per hour. A series of SiOₓ film thickness (7.3 nm˜167.4 nm) were obtained by controlling the growth time. The refractive index of the as-deposited film was about 1.43 which is slightly lower than that of thermal oxide (n˜1.46).

While the experimental examples discussed specifically utilized SiOₓ films deposited on silicon wafers using a LPD process, the systems and methods for improving the passivation effect substrates may be utilized on any suitable films formed by any deposition process.

Post-Annealing:

The as-deposited sample was placed in a programmable rapid thermal processer to undergo annealing in O₂ and Forming Gas ambient according to the parameters listed in Table 1. There was about one hour of interval between the two steps of annealing to allow the intermediate characterization. For comparison, single step of Forming Gas annealing, and O₂/Forming Gas two steps of annealing were also performed using about the same parameters.

TABLE 1
Parameters for the annealing in a rapid thermal processer
AG Associates Heatpulse 410.

| | | Flow | | | |
|---|---|---|---|---|---|
| | | Rate | Temperature | Ramp Rate | Dwelling |
| | Gas Ambient | (sccm) | (° C.) | (° C./s) | Time (s) |
| Step 1 | O₂ | 15 | 700-1050 | 50 | 30-120 |
| Step 2 | Forming Gas | 15 | 500 | 50 | 300 |
| | (N₂ mixed | | | | |
| | with 5% H₂) | | | | |

Characterization:

To evaluate the passivation effect of the LPD SiOₓ, a quasi-steady state photoconductance (QSSPC) lifetime measurement was performed with Sinton WCT120 at an injection level of 1×10¹⁵ cm⁻³ for each sample before and after each step of annealing. Some of the samples were tracked for months to identify the stability of the passivation effect in standard cleanroom ambient. secondary ion mass spectrometry (SIMS) measurements was performed for certain samples to explore the film composition variation induced by the annealing.

Results:

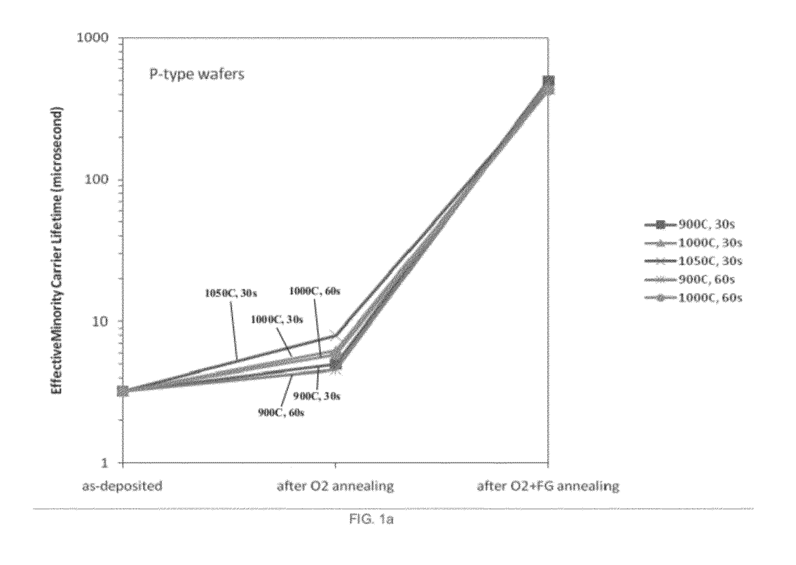

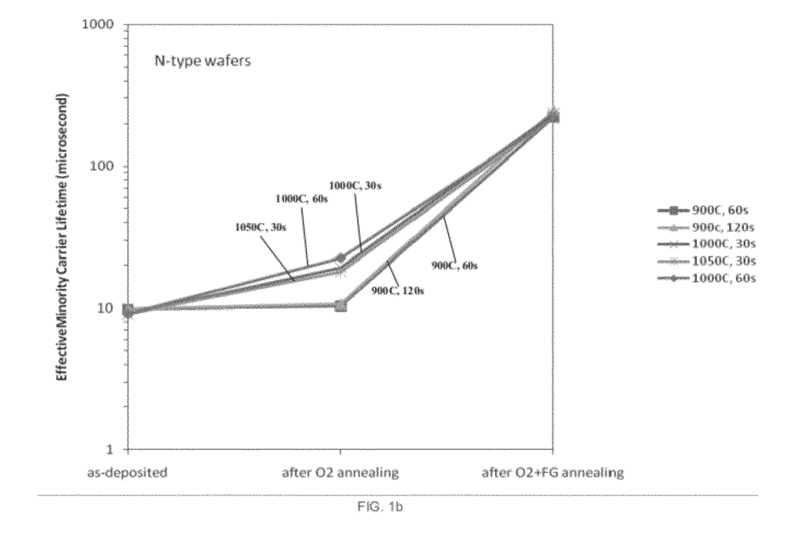

FIGS. 1a and 1b show the effective minority carrier lifetime comparison between the as-deposited sample, after O₂ annealing only, and after O₂+FG (two steps) annealing. The samples were measured immediately (in approximately ten minutes) after they were taken out of the annealing chamber. As can be seen, the lifetime increases mildly (up to 6 times) after O₂ annealing alone and increases sharply (about 20 times for N-type wafers and about 2 orders for P-type wafers) after O₂+FG annealing. It is theorized that annealing in O₂ can substitute F content in the as deposited LPD-SiOₓ film with O, leading to a more purified SiOₓ structure that has fewer electron and hole trap centers. Theoretically, with the high temperature annealing in O₂ ambient, the weak Si—F bonds are driven out, leaving only strong Si—F bonds in the film. Therefore, trap concentration relating to the incorporation of F in a SiO₂ film is reduced. On the other hand, the atomic hydrogen can diffuse to the Si/SiOₓ interface during FG annealing to reduce the interface state density by reacting with the dangling bonds. In brief, the annealing in O₂ and FG causes an orderly smaller surface recombination velocity due to the reduction of trap concentrations at the interface and oxide film thus increases the lifetime significantly for the minority carriers.

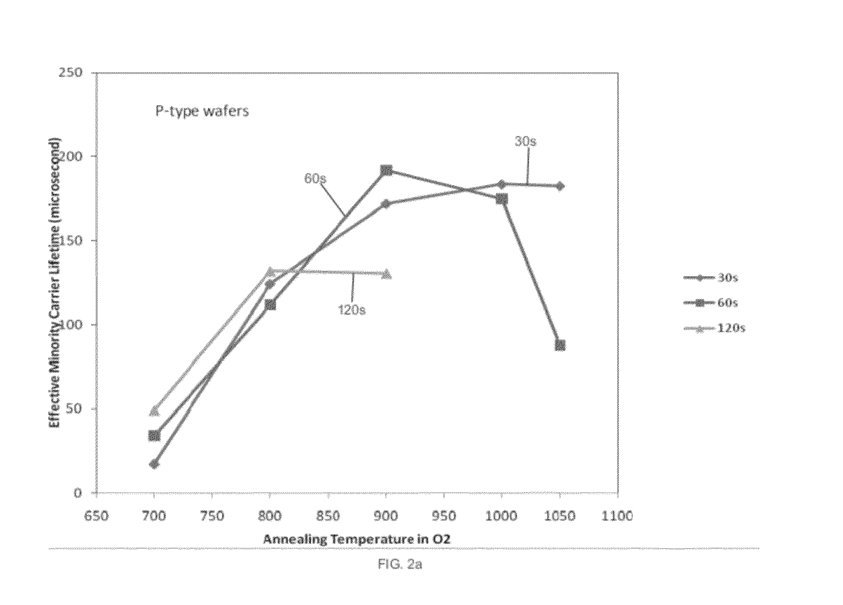

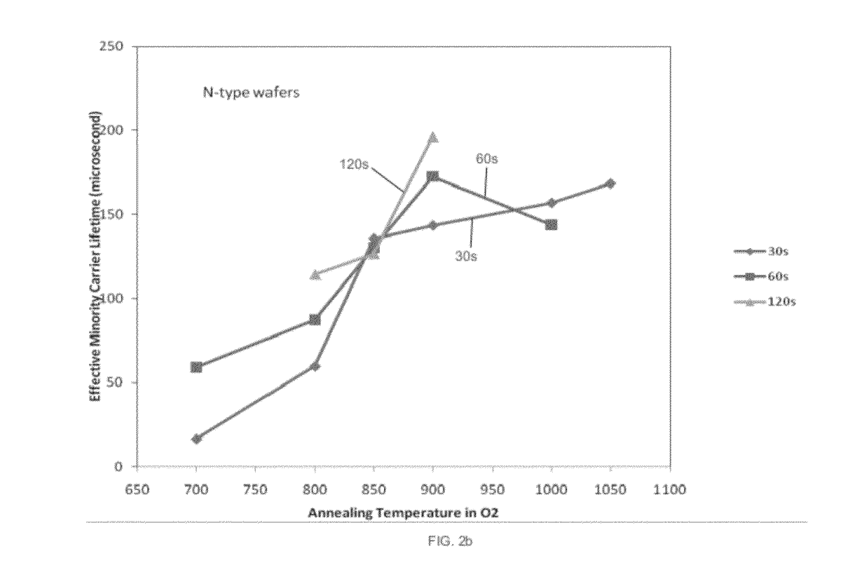

FIGS. 2a and 2b show O₂ annealing temperature dependent effective minority carrier lifetime of p-type wafers and n-type wafers. With the FG annealing condition fixed, the dependence of the effective lifetime on O₂ annealing temperature and dwelling time has been examined. FIGS. 2a and 2b show the measured effective lifetime of samples after six weeks of storage in the cleanroom ambient. For P-type wafers, the lifetime increases with the dwelling time for low temperature range (<=800° C.), while the longer time annealing at temperatures higher than 1000° C. reduce the lifetime. The optimal temperature and dwelling time turns out to be 900° C., 60 s. There are some deviations in the case of N-type wafers but with a similar trend. With a short annealing time of 30 s, higher temperature shows better results than lower temperature since the F content in the film is driven out fast at higher temperature. However, longer time (>=60 s) at high temperature (>=1000° C.) tends to degrade the wafers by generating more defects such as the boron-oxide composite defects in the P-type wafers therefore deteriorating the effective lifetime for the minority carriers.

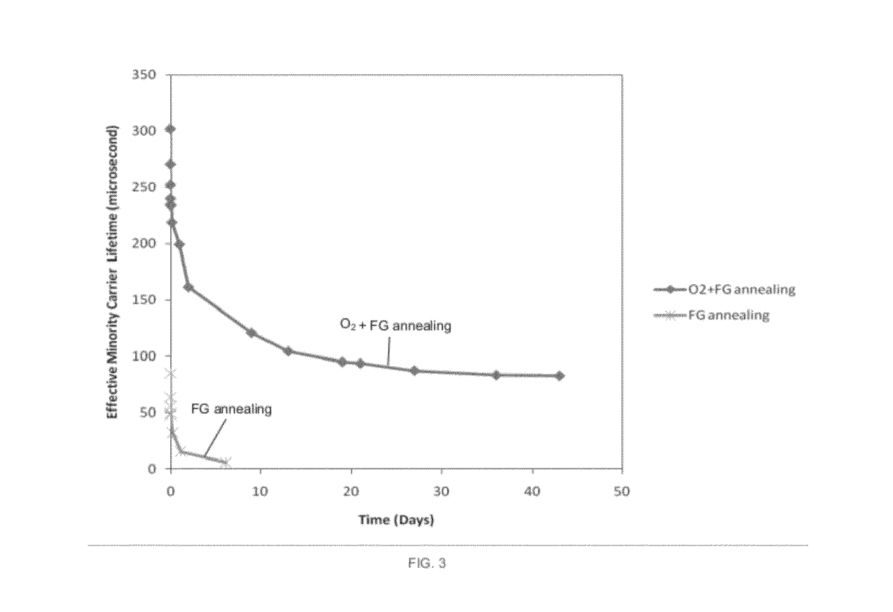

The stability of the annealing effect has been examined by tracking the effective lifetime of the post-annealed samples, as shown in FIG. 3. The exposure to the cleanroom ambient has significant impact on the post-annealed samples, especially at the first week. For the samples annealed only in FG, the lifetime dives to the same level of the as-deposited samples during one week of ambient exposure. In contrast, the sample with annealing in Q₂+FG has a superior stability at a long-term tracking. Together with FIG. 1, this indicates that O₂ annealing is an important step to enhance as well as stabilize the FG annealing effect.

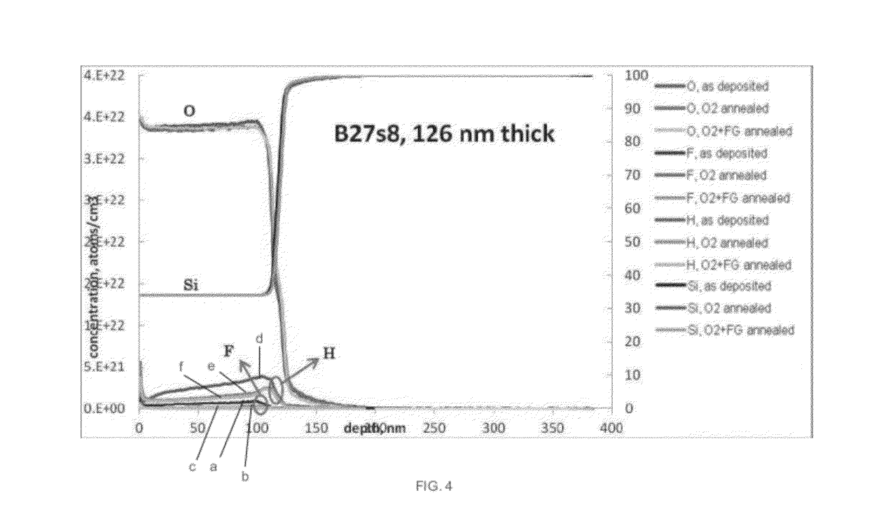

FIG. 4 shows secondary ion mass spectrometry (SIMS) measurements of LPD SiO_{X} film on Si substrate before, after annealing in O₂, and after annealing in O₂+FG. The concentration (atoms/cm³) at different depths (nm) is shown for silicon, oxygen, fluorine, and hydrogen as deposited, after O₂ annealing, and after O₂+FG annealing. The change of the profile of fluorine in the LPD SiOₓ film was monitored by SIMS measurement. The reduction of the fluorine composition after annealing is considered to be related to the improvement of passivation effect (a=F as deposited, b=F after O₂ annealing, c=F after O₂+FG annealing). The composition of fluorine (F) reduces by approximately an order after annealed in O₂. Since H and F may be present in the film in the form of HF or similar structure, the decrease in H may be correlated to the reduction of F in the film (d=H as deposited, e=H after O₂ annealing, f=H after O₂+FG annealing). With the high temperature annealing process, the HF could be easily evaporated from the film. During the annealing, the interface of SiOₓ/Si could also form a thin layer of thermal oxidation to improve the passivation. Annealing in FG further enhances the passivation of the SiO₂/Si interface with thermally driven H atom diffusion into the interface. The Si and O composition in the film is very stable before and after annealing. The O composition stays twice the Si composition after the annealing, which indicates that the film has very good thermal stability and suitable for use in solar cell coating applications.

By enhancing the surface passivation effect, the process will improve the device performance of the silicon solar cell that use LPD deposited silicon dioxide as the first layer coating on its surfaces. The process makes the LPD deposited silicon dioxide comparable to thermal oxide in term of surface passivation effect of Si substrate, potentially promoting the industrial application of LPD silicon dioxide to reduce the cost of the Si solar cell.

LPD deposited silicon dioxide is a low temperature process to achieve dielectric thin film on Si substrate, potentially reducing the energy consumption and the wafer thickness used in the fabrication of crystalline Si solar cells. The effective lifetime of minority carriers is a critical index to evaluate the passivation effect. To our best knowledge, there seems no report to date about how the minority carrier lifetime can be increased by annealing for the Si substrate with the LPD deposited silicon dioxide film. Our experiments demonstrated for the first time that the effective lifetime could be significantly improved by the annealing process compared to as-deposited samples, which represents a new feature. We believe that both the interface state density and the trap density in the film were significantly reduced after annealed in O₂ and FG subsequently.

Implementations described herein are included to demonstrate particular aspects of the present disclosure. It should be appreciated by those of skill in the art that the implementations described herein merely represent exemplary implementation of the disclosure. Those of ordinary skill in the art should, in light of the present disclosure, appreciate that many changes can be made in the specific implementations described and still obtain a like or similar result without departing from the spirit and scope of the present disclosure. From the foregoing description, one of ordinary skill in the art can easily ascertain the essential characteristics of this disclosure, and without departing from the spirit and scope thereof, can make various changes and modifications to adapt the disclosure to various usages and conditions. The implementations described hereinabove are meant to be illustrative only and should not be taken as limiting of the scope of the disclosure.

What is claimed is:

1. A method for improving a surface passivation of a semiconductor, the method comprising:
annealing a substrate with a film deposited on the surface of the substrate in a heating chamber at a first predetermined temperature, wherein the silicon wafer is annealed in a first gas ambient containing O₂ or O²⁻ for a first predetermined period of time; and
annealing the substrate at a second predetermined temperature in a second gas ambient containing H₂ or H⁺ for a second predetermined period of time.

2. The method of claim 1, wherein the film is SiO₂, TiO₂, ZrO₂, In₂O₃, SnO₂, BaTiO₃, ZnS, or Bi₂Se₃.

3. The method of claim 1, wherein the film is a metal oxide, metal sulfide, or metal selenide.

4. The method of claim 1, wherein the substrate is a silicon wafer.

5. The method of claim 1, wherein the first predetermined temperature is greater than or equal to 700° C. and less than or equal to 1050° C.

6. The method of claim 1, wherein the first predetermined temperature is less than or equal to 1050° C.

7. The method of claim 1, wherein the second predetermined temperature range is less than or equal to 600° C.

8. The method of claim 1, wherein the first gas ambient is purified air, purified oxygen, an O₂ and N₂ mixture, or purified de-ionized water steam.

9. The method of claim 1, wherein the second gas ambient is purified H₂ or purified de-ionized water steam.

10. The method of claim 1, wherein the first predetermined period of time is greater than or equal to 30 seconds and less than or equal to 120 seconds.

11. The method of claim 1, wherein the second predetermined period of time is greater than or equal to 60 seconds.

12. The method of claim 1, wherein the silicon wafer further comprises metal contacts, and the annealing in the second gas ambient also anneals the metal contacts.

13. The method of claim 9, wherein the metal contacts are a metal paste or deposited metal film.

14. A method for improving a surface passivation of a semiconductor, the method comprising:
annealing a silicon substrate with a silicon oxide (SiOₓ) film deposited on the surface of the substrate in a heating chamber at a first predetermined temperature, wherein the silicon wafer is annealed in a first gas ambient containing O₂ or O²⁻ for a first predetermined period of time.

15. The method of claim 14, further comprising
annealing the silicon substrate at a second predetermined temperature in a second gas ambient containing H₂ or H⁺ for a second predetermined period of time.

16. The method of claim 14, wherein the first predetermined temperature is greater than or equal to 700° C. and less than or equal to 1050° C.

17. The method of claim 14, wherein the second predetermined temperature range is less than or equal to 600° C.

18. The method of claim 14, wherein the first gas ambient is purified air, purified oxygen, an O₂ and N₂ mixture, or purified de-ionized water steam.

19. The method of claim 14, wherein the second gas ambient is purified H₂ or purified de-ionized water steam.

20. The method of claim 14, wherein the first predetermined period of time is greater than or equal to 30 seconds and less than or equal to 120 seconds.

21. The method of claim 14, wherein the second predetermined period of time is greater than or equal to 60 seconds.
